(19) United States
(12) Patent Application Publication
(10) Pub. No.: US 2026/0305277 A1
(43) Pub. Date: Oct. 1, 2026

(54) DEEP TRENCH INTERSECTIONS WITH CORNER ROUNDING

(71) Applicant: Texas Instruments Incorporated, Dallas, TX (US)

(72) Inventors: Josef Muenz, Muenchen (DE); Michael Enzelberger-Heim, Muenchen (DE)

(21) Appl. No.: 19/096,291

(22) Filed: Mar. 31, 2025

(51) Int. Cl. H01L 21/763; H01L 21/762; H10D 80/20

(52) U.S. Cl. CPC H10W 10/40; H10D 80/251; H10W 10/014; H10W 10/041; H10W 10/17

(57) ABSTRACT

Disclosed examples include microelectronic devices, e.g. Integrated circuits, and methods of making such devices. Examples include a semiconductor substrate having a top surface. A first trench in the substrate has a first linear edge that intersects the top surface and extends laterally in a first direction. A second trench in the substrate has a second linear edge that intersects the top surface and extends laterally in a different second direction. A connecting edge including two inflection points intersects the top surface and extends from the first linear edge to the second linear edge.

### TECHNICAL FIELD

This disclosure relates to the field of microelectronic devices, and more particularly, but not exclusively, to trench isolation structures.

### BACKGROUND

Semiconductor components are being continually improved to reliably operate with smaller feature sizes. Fabricating semiconductor devices that have smaller feature size while meeting performance and reliability specifications presents diverse challenges.

### SUMMARY

This summary is provided to introduce a brief overview of disclosed concepts in a simplified form that are further described below in the detailed description including the drawings provided. This summary is not intended to limit the scope of the disclosure or the claims.

Disclosed examples include microelectronic devices including, and methods of making such devices. In one example a microelectronic device, e.g. An integrated circuit, includes a semiconductor substrate, herein referred to as a substrate, having a top surface. A first trench in the substrate has a first linear edge that intersects the top surface and extends laterally in a first direction. A second trench in the substrate has a second linear edge that intersects the top surface and extends laterally in a different second direction. The first direction may be normal to the second direction. A connecting edge including two inflection points intersects the top surface and extends from the first linear edge to the second linear edge

### BRIEF DESCRIPTION OF THE VIEWS OF THE DRAWINGS

FIG. 1A is a planar view of an intersection between two trenches including connecting edges between the trench edges.

FIG. 1B is a planar view inset of a portion of a connecting edge of FIG. 1A.

FIG. 2A is a planar view of an intersection of three trenches including connecting edges between the trench edges.

FIG. 2B. Is a planar view of an alternative intersection of three trenches including connecting edges between the trench edges.

FIG. 3 is a planar view of an intersection of four trenches including connecting edges between the trench edges.

FIG. 4 is a planar view of an intersection of three trenches including connecting edges between the trench edges.

FIG. 5 is a sectional view as marked in FIG. 3.

FIG. 6 presents a method of forming an integrated circuit.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events unless otherwise stated. Furthermore, some of the illustrated acts or events may be omitted in some examples in accordance with the present disclosure.

In addition, although some of the examples illustrated herein are shown in two dimensional views with various regions having depth and width, it should be clearly understood that these regions are illustrations of only a portion of a device that is actually a three-dimensional structure. Accordingly, these regions will have three dimensions, including length, width, and depth, when fabricated on an actual device. Moreover, while the present disclosure may be illustrated by examples directed to active devices, it is not intended that these illustrations be a limitation on the scope or applicability of the present disclosure. It is not intended that the active devices of the present disclosure be limited to the physical structures illustrated. These structures are included to demonstrate the utility and application of the present disclosure to various examples.

Many microelectronic devices include trenches, including deep trenches, in the substrate for isolation between electrical components. The trenches are commonly filled with a dielectric layer or a combination of a dielectric layer and a conductive layer such as a polycrystalline silicon layer, referred to herein as polysilicon layer. In some cases, trenches may be used to electrically isolate transistors or other components from other circuit components to reduce electrical interactions. Trenches may have a closed-loop configuration around electrical components as they may need to completely surround the electrical component to provide the necessary electrical isolation. Trenches used in higher voltage applications may be wider than in lower voltage implementations to provide higher breakdown resistance.

In some circuit designs, isolation trenches may be configured using a “Manhattan” layout, with such trenches extending in mutually orthogonal directions (e.g. X and Y) in or over a semiconductor substrate. In such arrangement trenches extending along one axis will generally intersect trenches extending along the other axis. In some baseline arrangements such intersections may be formed according to design rules that include a central pillar of semiconductor substrate material to meet manufacturing objectives such as minimal dishing due to polishing the polysilicon trench-fill material. Such implantations may generally consume substrate area that could otherwise be used to form circuit devices, therefore resulting in larger die area. Some aspects of isolation trenches including such posts are described in U.S. Pat. No. 11,101,342, incorporated herein by reference in its entirety.

Examples of the present disclosure recognize the foregoing issues and provide intersection regions that reduce substrate area consumption relative to such baseline implementations. To reduce substrate area dedicated to isolation trench intersections, two adjacent trenches are joined to an intersection trench by a connecting edge having two inflection points. A curvature of the connecting edge has a transition between convex curvature and concave curvature at each inflection point. The trenches connect to the intersection trench via “necks” of narrower trench width, thus providing an intersection region with smaller lateral extent, or radius, than previously provided, resulting in reduced substrate area usage. Whereas the examples of the present disclosure may provide these and other beneficial effects, no particular result is a requirement unless explicitly recited in a particular claim.

A center point of the connecting edge, between the two inflection points, is recessed toward a center of the trench intersection. This connecting edge with the two inflection points and the recessed center point may enable placement of the electrical components closer to the intersection of the trenches, advantageously reducing area of the microelectronic device. This connecting edge with the two inflection points and the recessed center point may also provide a larger radius of curvature of the connecting edge at the center point than would be possible in a connecting edge without the inflection points, advantageously reducing stress in the substrate. At intersections of four trenches, with connecting edges that join pairs of adjacent trenches, having a recessed center point on each connecting edge may advantageously eliminate formation of substrate pillars at the center of the trench intersection, while providing the advantages of reduced device area and reduced substrate stress.

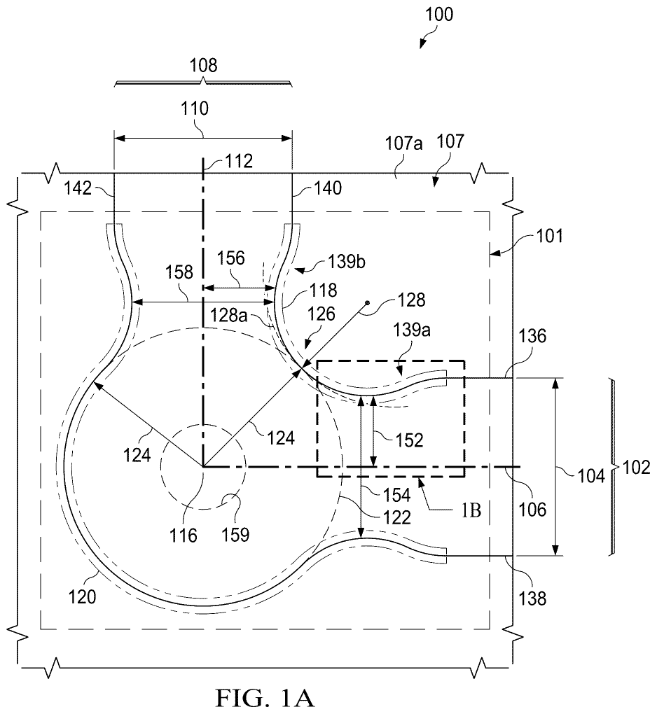

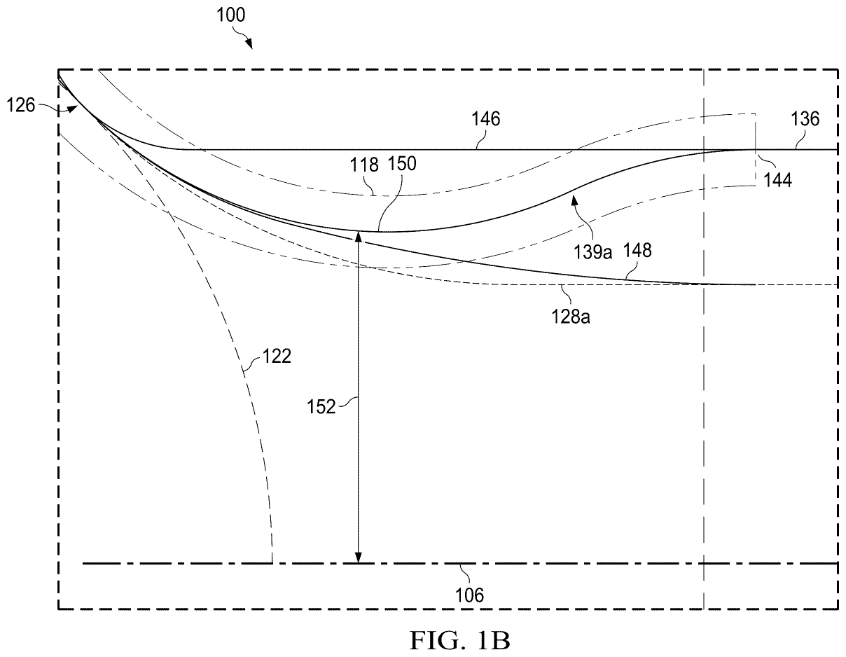

Referring to FIG. 1A, a planar representation is shown of a microelectronic device 100 at a top surface 107a of a substrate 107 including a first trench 102 and second trench 108 extending into the substrate 107 which meet in a trench intersection region 101. The first trench 102 has a first linear edge 136 sometimes referred to as a first trench first edge 136 and a fourth linear edge 138 sometimes referred to as a first trench second edge 138, the fourth linear edge 138 opposing the first linear edge 136, both of which define the edges where the first trench 102 intersects the top surface 107a of the substrate 107. The term “linear” in this context means the first linear edge 136 and the first trench second edge 138 which extend in a straight-line (rectilinear) fashion over the linear portion. The first trench 102 has a first trench width 104 and a first trench center line 106 that may be regarded as a major axis of the first trench 102. The first trench width 104 is along the minor axis of the first trench 102. The first trench 102 extends laterally along a major axis. The second trench 108 has an second linear edge 140 sometimes referred to as a second trench first edge 140 and an edge 142 sometimes referred to as a second trench second edge 142, both of which define the edges where the second trench 108 intersects the top surface 107a of the substrate 107. The second trench 108 has a second trench width 110 and a second trench center line 112 that may be regarded as a major axis of the second trench 108. The first trench center line 106 and the second trench center line 112 meet at a trench intersection center point 116. In some cases, the first trench 102, and the second trench 108 are normal to each other. The first trench first edge 136 contacts an end of a connecting edge 118, herein referred to as a first interior connecting edge 118 while the second trench first edge 140 contacts an opposite end of the first interior connecting edge 118. The first trench second edge 138 contacts an end of an exterior connecting edge 120 while the second trench second edge 142 contacts an opposite end of the exterior connecting edge 120. Substrate material of the substrate 107 is removed from the first trench 102, the second trench 108, and a portion of the trench intersection region 101 that is bounded by the first interior connecting edge 118 and the exterior connecting edge 120.

In the example shown in FIG. 1A, a trench intersection radius 124 extends from the trench intersection center point 116 to the first interior connecting edge 118 and to the exterior connecting edge 120, to define an intersection trench 122. The trench intersection radius 124 defines a circular intersection trench 122 that smoothly transitions to the first trench 102 and the second trench 108 via neck regions that are narrower than the first trench 102 and second trench 108. The intersection trench 122, the first trench 102, the second trench 108 and the transition areas between them may be filled with a dielectric material such as silicon nitride/silicon dioxide, or they may be filled with by a dielectric liner contacting the substrate 107 and a polysilicon layer contacting the dielectric liner which fills the remaining trench volume. While the intersection trench 122 is illustrated as circular, other shapes, such as ellipses, are within the scope of the disclosure.

The first interior connecting edge 118 is nearest to the first trench center line 106 at a point between the first trench 102 and the intersection trench 122, where a first edge minimum space 152 is a minimum distance between the first interior connecting edge 118 and the first trench center line 106. In some arrangements the first edge minimum space 152 may be less than half of the first trench width 104. The first interior connecting edge 118 and the exterior connecting edge 120 are separated by a first trench neck width 154 that is a minimum separation between the first interior connecting edge 118 and the exterior connecting edge 120, in a region between the first trench 102 and the intersection trench 122. The first trench neck width 154 is less than the first trench width 104 and less than a maximum width of the intersection trench 122 (e.g. Two times the trench intersection radius 124). In the example shown in FIG. 1A, the first trench neck width 154 is twice the first edge minimum space 152. In other versions of this example, the first trench neck width 154 may be larger than twice the first edge minimum space 152. The first trench neck width 154 and the first edge minimum space 152 may be offset from each other, and depicted in FIG. 1A, or may be colinear.

Similarly, the first interior connecting edge 118 is nearest to the second trench center line 112 at a point between the second trench 108 and the intersection trench 122, where a second edge minimum space 156 is a minimum distance between the first interior connecting edge 118 and the second trench center line 112. The second edge minimum space 156 may be less than half of the second trench width 110. The first interior connecting edge 118 and the exterior connecting edge 120 are separated by a second trench neck width 158 that is a minimum separation between the first interior connecting edge 118 and the exterior connecting edge 120, in a region between the second trench 108 and the intersection trench 122. The second trench neck width 158 may be less than the second trench width 110 and less than a maximum width of the intersection trench 122. In the example shown in FIG. 1A, the second trench neck width 158 may be twice the second edge minimum space 156. In other versions of this example, the second trench neck width 158 may be larger than twice the second edge minimum space 156. The second trench neck width 158 and the second edge minimum space 156 may be offset from each other, and depicted in FIG. 1A, or may be colinear.

The first trench 102, the second trench 108, and areas enclosed by the first interior connecting edge 118 and the exterior connecting edge 120, including the intersection trench 122, provide a trench structure in the substrate 107. The trench structure may be filled with a dielectric material or may be filled with a combination of a dielectric liner, e.g. Silicon dioxide and/or silicon nitride, contacting the substrate 107 and a conductive material, such as polysilicon, filling the interior of the trench (not specifically shown).

In the example shown in FIG. 1A, the first interior connecting edge 118 has a maximum radius of curvature 128 at a first connecting edge center point 126 of the first interior connecting edge 118. An arc 128a is tangent to the first interior connecting edge 118 at the first connecting edge center point 126, and has a radius of curvature equal to the maximum radius of curvature 128. The maximum radius of curvature 128 may be greater than 70 percent of the greater of the first trench width 104 and the second trench width 110, which may advantageously reduce stress in the substrate 107 due to dielectric material in the intersection trench 122.

In some examples the trench intersection radius 124 may be 50 percent to 100 percent of the greater of the first trench width 104 and the second trench width 110. In the example depicted in FIG. 1A, the trench intersection radius 124 is 83 percent to 93 percent of the greater of the first trench width 104 and the second trench width 110.

The first interior connecting edge 118 has two inflection points, a first inflection point 139a proximate to the first trench 102 and a second inflection point 139b proximate to the second trench 108. A curvature of the first interior connecting edge 118 transitions between convex curvature and concave curvature at each of the inflection points 139a and 139b. The first interior connecting edge 118 has concave curvature with respect to the first trench 102 from the first trench first edge 136 to the first inflection point 139a. The first interior connecting edge 118 has convex curvature with respect to the intersection trench 122 from the first inflection point 139a to the second inflection point 139b. The first interior connecting edge 118 has concave curvature with respect to the second trench 108 from the second inflection point 139b to the second trench first edge 140. Having the first inflection point 139a and the second inflection point 139b in the first interior connecting edge 118, optionally with the trench intersection radius 124 being 50 percent to 100 percent of the greater of the first trench width 104 and the second trench width 110, recesses the first connecting edge center point 126 toward the trench intersection center point 116 and may result in maintaining the maximum radius of curvature 128 at greater than 70 percent of the greater of the first trench width 104 and the second trench width 110. Recessing the first connecting edge center point 126 toward the trench intersection center point 116 may advantageously reduces the area of the intersection trench 122, which may allow improved utilization of substrate 107 area within a trench isolation region, compared to a connecting edge without inflection points.

Having the trench intersection radius 124 in a range from 50 percent to 100 percent of the greater of the first trench width 104 and the second trench width 110 may facilitate forming the intersection trench 122 concurrently with the first trench 102 and the second trench 108 with a uniform trench depth. This arrangement may further facilitate forming a trench fill material, such as silicon dioxide or polysilicon, in the intersection trench 122 and subsequently planarizing the trench fill material to facilitate patterning contacts over the intersection trench 122 without adding process complexity or cost. Such an arrangement may further facilitate forming a substrate contact 159 through a dielectric liner (not specifically shown) around the trench intersection center point 116 in the intersection trench 122. The substrate contact 159 may be formed by an anisotropic etch process, such as a deep reactive ion etch (DRIE) process, which may form a protective polymer on sidewalls of the first trench 102, the second trench 108, and the trench intersection region 101 that is bounded by the first interior connecting edge 118 and the exterior connecting edge 120. The substrate contact 159 may be formed without a dedicated photolithographically defined etch mask, advantageously reducing process cost and complexity. The substrate contact 159 may provide a substrate contact to the substrate 107 under the intersection trench 122 through a conductive material, such as polysilicon, in the intersection trench 122.

FIG. 1B is an inset view of FIG. 1A which highlights one possible shape of the first interior connecting edge 118 between the first connecting edge center point 126 of the first interior connecting edge 118 and the first trench first edge 136 at a first trench first edge endpoint 144. The first interior connecting edge 118 is tangent to the arc 128a at the first connecting edge center point 126. The arc 128a has the maximum radius of curvature 128. The maximum radius of curvature 128 in this example is equal to the first trench width 104. The remaining portions of the first interior connecting edge 118 may have a radius of curvature less than the maximum radius of curvature 128. It may be advantageous for the first interior connecting edge 118 to have a radius of curvature smaller than the maximum radius of curvature 128 at all points other than the first connecting edge center point 126 so as to generate a profile in which the first edge minimum space 152, the distance from the nearest point on first interior connecting edge 118 to the first trench center line 106 is less than half the first trench width 104.

While multiple methods may be used to generate the curve of the first interior connecting edge 118 between the first connecting edge center point 126 and the first trench first edge endpoint 144 of the first trench first edge 136, an example method is herein is described. A coordinate system may be used with the first trench first edge endpoint 144 being point A, and the first connecting edge center point 126 being point B. The resulting x-y coordinate system is:

$${x}_{A} = 1.5 w \qquad Eqn . 1$$

$${y}_{A} = 0 \text{.5000} w \qquad Eqn . 2$$

$${x}_{B} = 0.625 w \qquad Eqn . 3$$

$${y}_{B} = {x}_{B} \qquad Eqn . 4$$

where w is the first trench width 104.

The first interior connecting edge 118 between the first connecting edge center point 126 of the first interior connecting edge 118 and the first trench first edge endpoint 144 of the first interior connecting edge 118 is a derived line 150 defined by a function ƒ which is a superposition of a first guiding function ƒ₍₁₎ 146 and a second guiding function ƒ₍₂₎ 148.

The first guiding function ƒ₍₁₎ 146 is defined in two ranges. A first range consists of an arc of a circle, and a second range consists of a line segment.

$$For {x}_{B} \leq x \leq 0.9267 w : \qquad Eqn . 5$$

$${f}_{( 1 )} = 0.9267 w - \sqrt{0.181 {w}^{2} - {[ x - ( 0 \text{.9267} w ) ]}^{2}}$$

$$For 0.9287 w \leq x \leq {x}_{A} \qquad Eqn . 6$$

$${f}_{( 1 )} = 0 \text{.5000} w$$

The second guiding function ƒ₍₂₎ 148 is also defined in two ranges. A first range consists of an arc of a circle, and a second range consists of a line segment.

$$For {x}_{B} \leq x \leq 1.3 \; 321 w : \qquad Eqn . 7$$

$${f}_{( 2 )} = 1.3321 w - \sqrt{{w}^{2} - {( x - 1.3321 w )}^{2}}$$

$$For 1.3321 w \leq x \leq {x}_{A} \qquad Eqn . 8$$

$${f}_{( 2 )} = 0.3321 w$$

A superposition coordinate u is defined as a fraction of the space at the coordinate x between x_{A} and x_{B}:

$$u = \frac{x - {x}_{B}}{{x}_{A} - {x}_{B}} with {x}_{B} \leq x \leq {x}_{A} \qquad Eqn . 9$$

A guiding weight function g_{w}(u) is defined to provide a smooth transition from the first guiding function ƒ₍₁₎ 146 to the second guiding function ƒ₍₂₎ 148 over the space between x_{A} and x_{B}:

$${g}_{w} ( u ) = 2 ( u + ( \frac{1}{2} ) ) {( u - 1 )}^{2} for 0 \leq u \leq 1 \qquad Eqn . 10$$

The resulting function ƒ(x) between point A and point B is a weighted linear combination of the guiding functions ƒ₁(x) and ƒ₂(x). Coefficients of the weighted linear combination are provided by the guiding weight function g_{w}(u). The function ƒ(x) may be defined as:

$$f ( x ) = ( 1 - {g}_{w} ( u ) ) {f}_{1} ( x ) + {g}_{w} ( u ) {f}_{2} ( x ) for {x}_{B} \leq x \leq {x}_{A} \qquad Eqn . 11$$

While the function shown above is one method of generating the first interior connecting edge 118 from the first connecting edge center point 126 (point B) to the first trench first edge endpoint 144 (point A), multiple other functions may generate advantageous solutions.

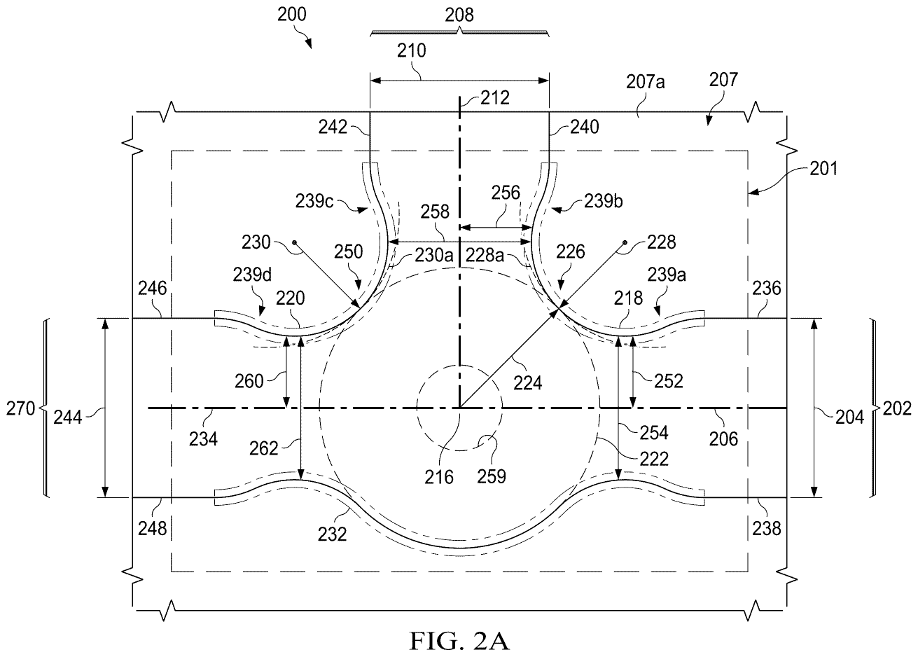

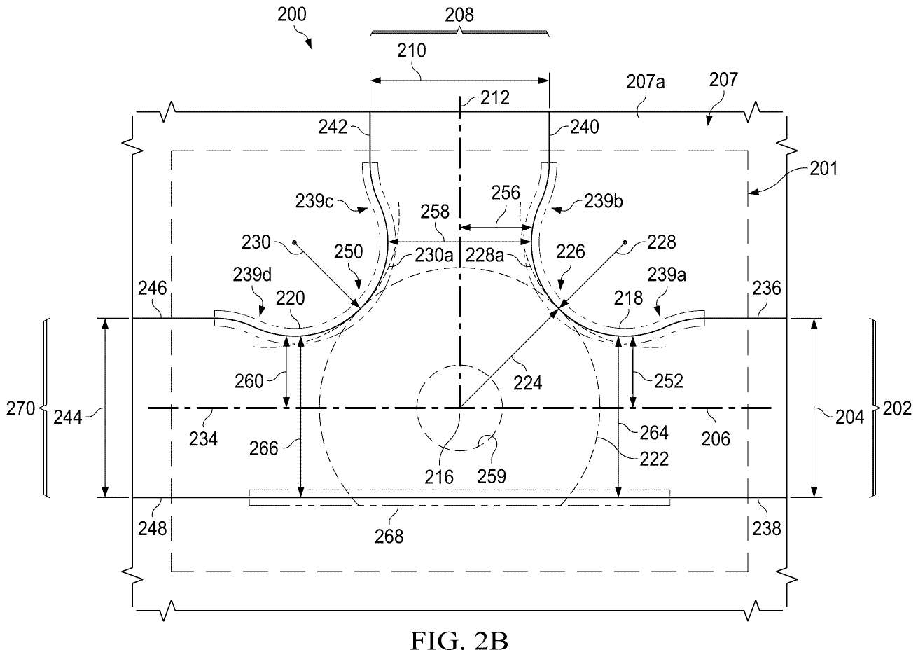

Referring to FIG. 2A, which is a planar view, a microelectronic device 200 includes a first trench 202, a second trench 208, and a third trench 270, in a substrate 207, extending to a top surface 207a of the substrate 207. The first trench 202, the second trench 208, and the third trench 270 meet at a trench intersection region 201. The first trench 202 has a first linear edge 236 sometimes referred to as a first trench first edge 236 and a fourth linear edge 238 sometimes referred to as a first trench second edge 238, both of which define the edges where the first trench 202 intersects the top surface 207a of the substrate 207. The first trench 202 has a first trench width 204 and a first trench center line 206 that may be regarded as a major axis of the first trench 202.

The second trench 208 has a second linear edge 240 sometimes referred to as a second trench first edge 240 and an edge 242 sometimes referred to as a second trench second edge 242, both of which define the edges where the second trench 208 intersects the top surface 207a of the substrate 207. The second trench 208 has a second trench width 210 and a second trench center line 212 that may be regarded as a major axis of the second trench 208.

The third trench 270 has an edge 246 sometimes referred to as a third trench first edge 246 and a third linear edge 248 sometimes referred to as a third trench second edge 248, both of which define the edges where the third trench 270 intersects the top surface 207a of the substrate 207. The third trench 270 has a third trench width 244 and a third trench center line 234 that may be regarded as a major axis of the third trench 270.

The first trench center line 206, the second trench center line 212, and the third trench center line 234 meet at a trench intersection center point 216. A connecting edge 218 herein referred to as a first interior connecting edge 218 extends between the first trench first edge 236 and the second trench first edge 240. A connecting edge 220 herein referred to as a second interior connecting edge 220 extends between the second trench second edge 242 and the third trench first edge 246. A exterior connecting edge 232 extends between the third linear edge 248 sometimes referred to as the third trench second edge 248 and the fourth linear edge 238 sometimes referred to as the first trench second edge 238. In the arrangement depicted in FIG. 2A, the exterior connecting edge 232, is coincident with a portion of the edge of an intersection trench 222. The intersection trench 222 extends to the first interior connecting edge 218 and to the second interior connecting edge 220. Substrate material of the substrate 207 is removed from the first trench 202, the second trench 208, the third trench 270, and a portion of the trench intersection region 201 that is bounded by the first interior connecting edge 218, the second interior connecting edge 220, and the exterior connecting edge 232.

A trench intersection radius 224 extends from the trench intersection center point 216 to the first interior connecting edge 218, to the second interior connecting edge 220, and to exterior connecting edge 232, to define an intersection trench 222. The trench intersection radius 224 defines a circular intersection trench 222 that smoothly transitions to the first trench 202, the second trench 208, and the third trench 270 via neck regions that are narrower than the first trench 202, the second trench 208, and third trench 270. While the intersection trench 222 is illustrated as circular, other shapes, such as ellipses, are within the scope of the disclosure.

The first interior connecting edge 218 is nearest to the first trench center line 206 at a point between the first trench 202 and the intersection trench 222, where a first edge minimum space 252 is a minimum distance between the first interior connecting edge 218 and the first trench center line 206. In some arrangements the first edge minimum space 252 may be less than half of the first trench width 204. The first interior connecting edge 218 and the exterior connecting edge 232 are separated by a first trench neck width 254 that is a minimum separation between the first interior connecting edge 218 and the exterior connecting edge 232, in a region between the first trench 202 and the intersection trench 222. The first trench neck width 254 is less than the first trench width 204 and less than a maximum width of the intersection trench 222 (e.g. Two times the trench intersection radius 224). In the example shown in FIG. 2A, the first trench neck width 254 is twice the first edge minimum space 252. In other versions of this example, the first trench neck width 254 may be larger than twice the first edge minimum space 252. The first trench neck width 254 and the first edge minimum space 252 may be offset from each other, and depicted in FIG. 2A, or may be colinear.

The first interior connecting edge 218 is nearest to the second trench center line 212 at a point between the second trench 208 and the intersection trench 222, where a second edge minimum space 256 is a minimum distance between the first interior connecting edge 218 and the second trench center line 212. The second edge minimum space 256 may be less than half of the second trench width 210. The first interior connecting edge 218 and the second interior connecting edge 220 are separated by a second trench neck width 258 that is a minimum separation between the first interior connecting edge 218 and the second interior connecting edge 220, in a region between the second trench 208 and the intersection trench 222. The second trench neck width 258 may be less than the second trench width 210 and less than a maximum width of the intersection trench 222. In the example shown in FIG. 2A, the second trench neck width 258 may be twice the second edge minimum space 256. The second trench neck width 258 and the second edge minimum space 256 may be offset from each other, and depicted in FIG. 2A, or may be colinear.

The second interior connecting edge 220 is nearest to the third trench center line 234 at a point between the third trench 270 and the intersection trench 222, where a third edge minimum space 260 is a minimum distance between the second interior connecting edge 220 and the third trench center line 234. The third edge minimum space 260 is less than half of the third trench width 244. The second interior connecting edge 220 and the exterior connecting edge 232 are separated by a third trench neck width 262 that is a minimum separation between the second interior connecting edge 220 and the exterior connecting edge 232, in a region between the third trench 270 and the intersection trench 222. The third trench neck width 262 is less than the third trench width 244 and less than a maximum width of the intersection trench 222. In the example shown in FIG. 2A, the third trench neck width 262 is twice the third edge minimum space 260. In other versions of this example, the third trench neck width 262 may be larger than twice the third edge minimum space 260. The third trench neck width 262 and the third edge minimum space 260 may be offset from each other, and depicted in FIG. 2A, or may be colinear.

The first trench 202, the second trench 208, the third trench 270, and areas enclosed by the first interior connecting edge 218, the second interior connecting edge 220, and the exterior connecting edge 232, including the intersection trench 222, provide a trench structure in the substrate 207. The trench structure may be filled with a dielectric material or may be filled with a combination of a dielectric liner contacting the substrate 207 and a conductive material, such as polysilicon, filling the interior of the trench (not specifically shown).

In the example shown in FIG. 2A, the first interior connecting edge 218 has a first maximum radius of curvature 228 at a first connecting edge center point 226 of the first interior connecting edge 218. A first arc 228a is tangent to the first interior connecting edge 218 at the first connecting edge center point 226, and has a radius of curvature equal to the first maximum radius of curvature 228. The first maximum radius of curvature 228 may be greater than 70 percent of the greater of the first trench width 204 and the second trench width 210, which may advantageously reduce stress in the substrate 207 due to dielectric material in the intersection trench 222.

The second interior connecting edge 220 has a second maximum radius of curvature 230 at a second connecting edge center point 250 of the second interior connecting edge 220. A second arc 230a is tangent to the second interior connecting edge 220 at the second connecting edge center point 250, and has a radius of curvature equal to the second maximum radius of curvature 230. The second maximum radius of curvature 230 may be greater than 70 percent of the greater of the second trench width 210 and the third trench width 244, which may advantageously reduce stress in the substrate 207 due to dielectric material in the intersection trench 222.

Analogous to the device 100, the trench intersection radius 224 may in some examples be 50 percent to 100 percent of the greater of the first trench width 204, the second trench width 210, and the third trench width 244. In the version of this example depicted in FIG. 2A, the trench intersection radius 224 is 83 percent to 93 percent of the greater of the first trench width 204, the second trench width 210, and the third trench width 244.

The first interior connecting edge 218 has two inflection points, an inflection point 239a proximate to the first trench 202 and an inflection point 239b proximate to the second trench 208. A curvature of the first interior connecting edge 218 transitions between convex curvature and concave curvature at each of the inflection points 239a and 239b. The first interior connecting edge 218 has concave curvature with respect to the first trench 202 from the first trench first edge 236 to the inflection point 239a. The first interior connecting edge 218 has convex curvature from the inflection point 239a to the inflection point 239b with respect to the intersection trench 222. The first interior connecting edge 218 has concave curvature from the inflection point 239b to the second trench first edge 240 with respect to the second trench 208. Locating of the inflection point 239a and the inflection point 239b in the first interior connecting edge 218, with the trench intersection radius 224 in some arrangements in a range from 50 percent to 100 percent of the greater of the first trench width 204, the second trench width 210, and the third trench width 244, recesses the first connecting edge center point 226 toward the trench intersection center point 216 while maintaining the first maximum radius of curvature 228 at greater than 70 percent of the greater of the first trench width 204 and the second trench width 210. Recessing the first connecting edge center point 226 toward the trench intersection center point 216 may advantageously reduces the area of the intersection trench 222, which may allow improved utilization of substrate 207 area within a trench isolation region, compared to a connecting edge without inflection points.

The second interior connecting edge 220 has two inflection points, an inflection point 239c proximate to the second trench 208 and an inflection point 239d proximate to the third trench 270. A curvature of the second interior connecting edge 220 transitions between convex curvature and concave curvature at each of the inflection points 239c and 239d. The second interior connecting edge 220 has concave curvature from the second trench second edge 242 to the inflection point 239c with respect to the second trench 208. The second interior connecting edge 220 has convex curvature from the inflection point 239c to the inflection point 239d with respect to the intersection trench 222. The second interior connecting edge 220 has concave curvature from the inflection point 239d to the third trench first edge 246 with respect to the third trench 270. Having the inflection point 239c and the inflection point 239d in the second interior connecting edge 220, with the trench intersection radius 224 in a range from 50 percent to 100 percent of the greater of the first trench width 204, the second trench width 210, and the third trench width 244, recesses the second connecting edge center point 250 toward the trench intersection center point 216 while maintaining the second maximum radius of curvature 230 at greater than 70 percent of the greater of the second trench width 210 and the third trench width 244. Recessing the second connecting edge center point 250 toward the trench intersection center point 216 advantageously reduces the area of the intersection trench 222, which may allow improved utilization of substrate 207 area within a trench isolation region, compared to a connecting edge without inflection points.

Having the trench intersection radius 224 in a range from 50 percent to 100 percent of the greater of the first trench width 204, the second trench width 210, and the third trench width 244 may enable forming the intersection trench 222 concurrently with the first trench 202, the second trench 208, and the third trench 270 with a uniform trench depth. Having the trench intersection radius 224 in a range 50 percent to 100 percent of the greater of the first trench width 204, the second trench width 210, and the third trench width 244 may enable forming a trench fill material, such as a dielectric or a dielectric liner with a polysilicon trench fill, in the intersection trench 222 and subsequently planarizing the trench fill material to enable patterning contacts over the intersection trench 222 without adding process complexity or cost. Having the trench intersection radius 224 in a range from 50 percent to 100 percent of the greater of the first trench width 204, the second trench width 210, and the third trench width 244 may further enable forming a substrate contact 259 through a dielectric liner, not specifically shown, around the trench intersection center point 216 in the intersection trench 222. The substrate contact 259 may be formed as disclosed in reference to FIG. 1A, and may accrue similar advantages

FIG. 2B is a planar representation of another version of the microelectronic device 200 including the first trench 202, the second trench 208 and the third trench 270 which meet in the trench intersection region 201. The first interior connecting edge 218 and the second interior connecting edge 220 are similar to those shown in FIG. 2A with inflection points 239a, 239b, 239c, and 239d, and a first connecting edge center point 226 and second connecting edge center point 250.

The first interior connecting edge 218 has the first maximum radius of curvature 228 at the first connecting edge center point 226, and is tangent to the first arc 228a having the radius of curvature equal to the first maximum radius of curvature 228. The second interior connecting edge 220 has the second maximum radius of curvature 230 at the second connecting edge center point 250, and is tangent to the second arc 230a having the radius of curvature equal to the second maximum radius of curvature 230.

The version of the microelectronic device 200 of FIG. 2B has a linear connecting edge 268 which may sometimes be referred to as an exterior connecting edge 268 which contacts the third trench second edge 248 and the first trench second edge 238 and forms a straight line between them. FIG. 2B is an example of a case in which first trench neck width 264 may be larger than twice the first edge minimum space 252, but is less than the first trench width 204. The third trench intersection space 266 may be larger than twice the third edge minimum space 260, but is less than the third trench width 244. The linear configuration of the exterior connecting edge 268 may advantageously reduce area of the intersection trench 222.

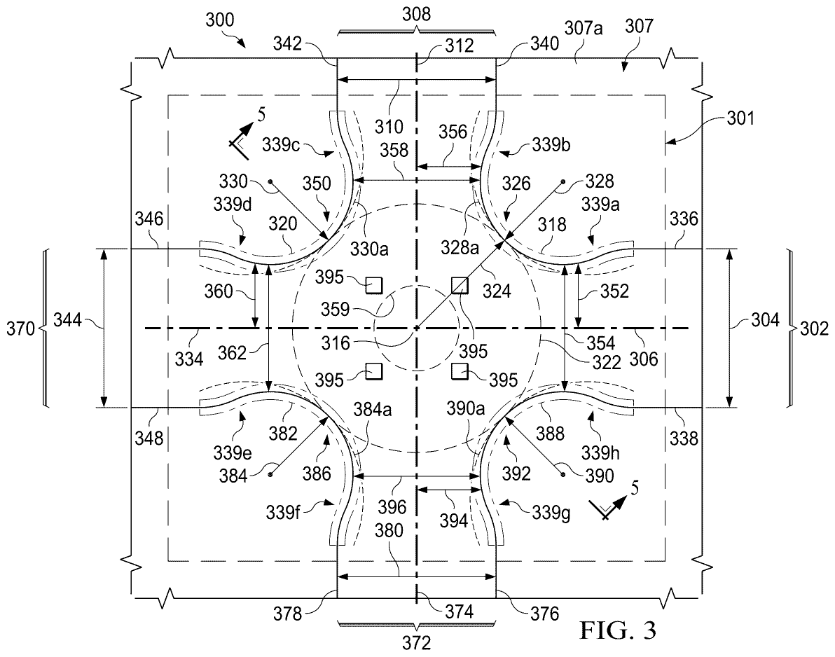

Referring to FIG. 3 a planar representation of a microelectronic device 300, at a top surface 307a of a substrate 307 including a first trench 302, a second trench 308, a third trench 370, and a fourth trench 372 extending into the substrate 307, which meet in a trench intersection region 301 is shown. The first trench 302 has a first edge 336 sometimes referred to as a first trench first edge 336 and an fourth edge 338 sometimes referred to as a first trench second edge 338, both of which define the edges where the first trench 302 intersects the top surface 307a of the substrate 307. The first trench 302 has a first trench width 304 and a first trench center line 306.

The second trench 308 has a second edge 340 sometimes referred to as a second trench first edge 340 and an edge 342 sometimes referred to as a second trench second edge 342, both of which define the edges where the second trench 308 intersects the top surface 307a of the substrate 307. The second trench 308 has a second trench width 310 and a second trench center line 312.

The third trench 370 has an edge 346 sometimes referred to as a third trench first edge 346 and a third edge 348 sometimes referred to as a third trench second edge 348, both of which define the edges where the third trench 370 intersects the top surface 307a of the substrate 307. The third trench 370 has a third trench width 344 and a third trench center line 334.

The fourth trench 372 has an edge 378 sometimes referred to as a fourth trench first edge 378 and an edge 376 sometimes referred to as a fourth trench second edge 376, both of which define the edges where the fourth trench 372 intersects the top surface 307a of the substrate 307. The fourth trench 372 has a fourth trench width 380 and a fourth trench center line 374.

The first trench center line 306, second trench center line 312, the third trench center line 334, and the fourth trench center line 374 meet at a trench intersection center point 316.

The first trench first edge 336 contacts an end of a connecting edge 318 herein referred to as a first interior connecting edge 318 while the second trench first edge 340 contacts an opposite end of the first interior connecting edge 318. The first interior connecting edge 318 contains two inflection points, a first inflection point 339a and a second inflection point 339b.

The second trench second edge 342 contacts an end of a connecting edge 320 herein referred to as a second interior connecting edge 320 while the third trench first edge 346 contacts an opposite end of the second interior connecting edge 320. The second interior connecting edge 320 contains two inflection points, a third inflection point 339c and a fourth inflection point 339d.

The third trench second edge 348 contacts an end of a connecting edge 382 herein referred to as a third interior connecting edge 382 while the fourth trench first edge 378 contacts an opposite end of the third interior connecting edge 382. The third interior connecting edge 382 contains two inflection points, a fifth inflection point 339e and a sixth inflection point 339f.

The fourth trench second edge 376 contacts an end of a connecting edge 388 herein referred to as a fourth interior connecting edge 388 while the first trench second edge 338 contacts an opposite end of the fourth interior connecting edge 388. The fourth interior connecting edge 388 contains two inflection points, a seventh inflection point 339g and an eighth inflection point 339h.

A trench intersection radius 324 extends from the trench intersection center point 316 to the first interior connecting edge 318, to the second interior connecting edge 320, to the third interior connecting edge 382, and to the fourth interior connecting edge 388, to define an intersection trench 322. Analogous to previous examples, the trench intersection radius 324 may be in a range from 50 percent to 100 percent of the greater of the first trench width 304, the second trench width 310, the third trench width 344, and the fourth trench width 380. Similar to previous examples, the intersection trench 322 may include a substrate contact 359.

The first interior connecting edge 318 has a first maximum radius of curvature 328 at a first connecting edge center point 326 of the first interior connecting edge 318. A first arc 328a is tangent to the first interior connecting edge 318 at the first connecting edge center point 326, and has a radius of curvature equal to the first maximum radius of curvature 328. The first maximum radius of curvature 328 may be greater than 70 percent of the greater of the first trench width 304 and the second trench width 310.

The second interior connecting edge 320 has a second maximum radius of curvature 330 at a second connecting edge center point 350 of the second interior connecting edge 320. A second arc 330a is tangent to the second interior connecting edge 320 at the second connecting edge center point 350, and has a radius of curvature equal to the second maximum radius of curvature 330. The second maximum radius of curvature 330 may be greater than 70 percent of the greater of the second trench width 310 and the third trench width 344.

The third interior connecting edge 382 has a third maximum radius of curvature 384 at a third connecting edge center point 386 of the third interior connecting edge 382. A third arc 384a is tangent to the third interior connecting edge 382 at the third connecting edge center point 386, and has a radius of curvature equal to the third maximum radius of curvature 384. The third maximum radius of curvature 384 may be greater than 70 percent of the greater of the third trench width 344 and the fourth trench width 380.

The fourth interior connecting edge 388 has a fourth maximum radius of curvature 390 at a fourth connecting edge center point 392 of the fourth interior connecting edge 388. A fourth arc 390a is tangent to the fourth interior connecting edge 388 at the fourth connecting edge center point 392, and has a radius of curvature equal to the fourth maximum radius of curvature 390. The fourth maximum radius of curvature 390 may be greater than 70 percent of the greater of the fourth trench width 380 and the first trench width 304.

A first edge minimum space 352 is a minimum distance between the first interior connecting edge 318 and the first trench center line 306. The first edge minimum space 352 is less than half of the first trench width 304. A first trench neck width 354 is a minimum distance between the first interior connecting edge 318 and the fourth interior connecting edge 388. The first trench neck width 354 is less than the first trench width 304 and less than a maximum width of the intersection trench 322.

A second edge minimum space 356 is a minimum distance between the first interior connecting edge 318 and the second trench center line 312. The second edge minimum space 356 is less than half of the second trench width 310. A second trench neck width 358 is a minimum distance between the first interior connecting edge 318 and the second interior connecting edge 320. The second trench neck width 358 is less than the second trench width 310 and less than a maximum width of the intersection trench 322.

A third edge minimum space 360 is a minimum distance between the second interior connecting edge 320 and the third trench center line 334. The third edge minimum space 360 is less than half of the third trench width 344. A third trench neck width 362 is a minimum distance between the second interior connecting edge 320 and the third interior connecting edge 382. The third trench neck width 362 is less than the third trench width 344 and less than a maximum width of the intersection trench 322.

A fourth edge minimum space 394 is a minimum distance between the fourth interior connecting edge 388 and the fourth trench center line 374. The fourth edge minimum space 394 is less than half of the fourth trench width 380. A fourth trench neck width 396 is a minimum distance between the third interior connecting edge 382 and the fourth interior connecting edge 388. The fourth trench neck width 396 is less than the fourth trench width 380 and less than a maximum width of the intersection trench 322.

In one version of this example, one or more contacts 395 may be placed in the trench intersection region 301 on a conductive trench-fill material, such as polysilicon (not specifically shown). The contacts 395 may extend from the conductive trench-fill material to an interconnect metal feature (not specifically shown), through a pre-metal dielectric (not specifically shown). The conductive trench-fill material may be formed by forming a layer of the conductive trench-fill material over the substrate 307 that fills the intersection trench 322 and the trenches 302, 308, 370, and 372, and subsequently removing the conductive trench-fill material from over the top surface 307a by an etchback process and/or a chemical mechanical polish (CMP) process. In examples for which the trench intersection radius 324 in a range from 50 percent to 100 percent of the greater of the first trench width 304, the second trench width 310, the third trench width 344, and the fourth trench width 380, forming the trench fill material in the intersection trench 322 and subsequently planarizing the trench fill material may provide for patterning the contacts 395 over the intersection trench 322 without adding process complexity or cost, compared to implementations that include an intersection trench with radius greater than 100% of the largest width of the trenches 302, 308, 370, and 372.

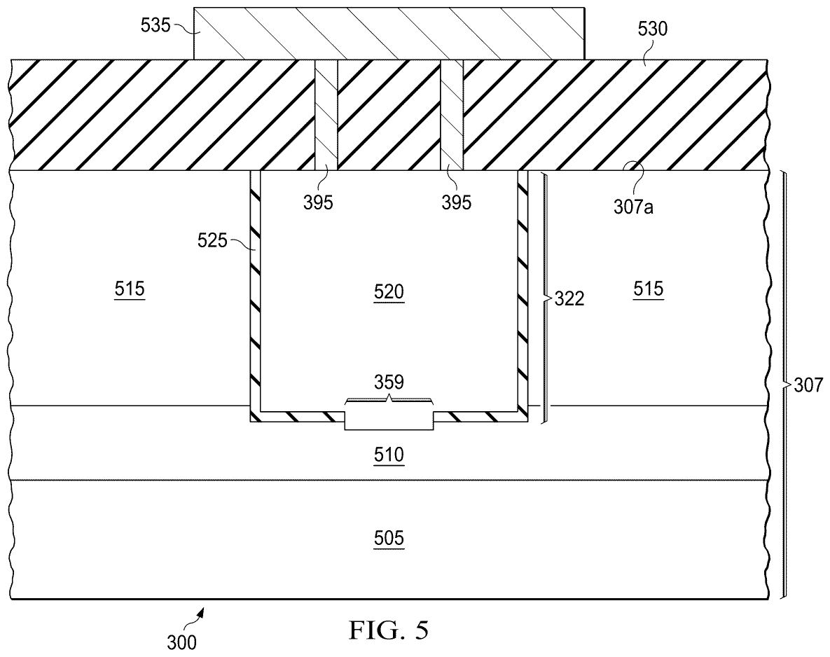

FIG. 5 is a sectional view as marked in FIG. 3, showing an example implementation of the intersection trench 322. The substrate 307 may include a base substrate such as a bulk semiconductor layer 505, a buried layer 510 and an epitaxial layer 515. In one example, the bulk semiconductor layer 505 and epitaxial layer 515 may be p-type and the buried layer may be n-type. The intersection trench 322 extends from the top surface 307a into the epitaxial layer 515 and is filled by polysilicon 520. An dielectric layer 525 is between the polysilicon 520 and the epitaxial layer 515. The substrate contact 359 includes a polysilicon portion contiguous with the polysilicon 520 that extends to the buried layer 510. A dielectric layer 530, e.g. A pre-metal dielectric, overlies the epitaxial layer 515 and the polysilicon 520, and the contacts 395 extend through the dielectric layer 530 to an interconnect metal feature 535.

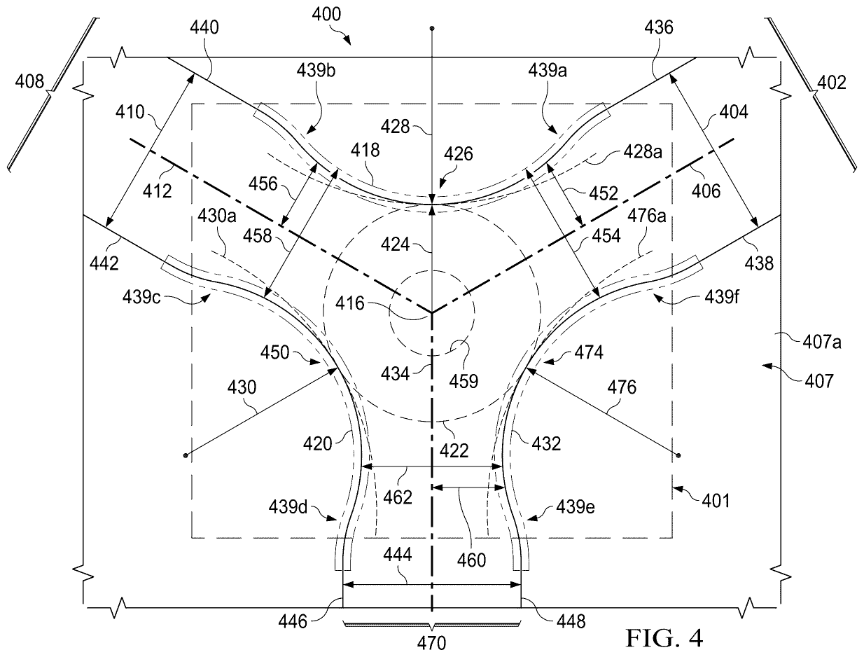

Referring to FIG. 4 a planar representation of a microelectronic device 400, at a top surface 407a of a substrate 407 including a first trench 402 and second trench 408 and a third trench 470 extending into the substrate 407 which meet in a trench intersection region 401, is shown. The first trench 402 has a first edge 436 sometimes referred to as the first trench first edge 436 and a fourth edge 438 sometimes referred to as the first trench second edge 438, both of which define the edges where the first trench 402 intersects the top surface 407a of the substrate 407. The first trench 402 has a first trench width 404 and a first trench center line 406.

The second trench 408 has a second edge 440 sometimes referred to as a second trench first edge 440 and an edge 442 sometimes referred to as a second trench second edge 442, both of which define the edges where the second trench 408 intersects the top surface 407a of the substrate 407. The second trench 408 has a second trench width 410 and a second trench center line 412.

The third trench 470 has an edge 446, sometimes referred to as the third trench first edge 446 and a third edge 448, sometimes referred to as the third trench second edge 448, both of which define the edges where the third trench 470 intersects the top surface 407a of the substrate 407. The third trench 470 has a third trench width 444 and a third trench center line 434.

The first trench center line 406, second trench center line 412, and the third trench center line 434 meet at a trench intersection center point 416.

The first trench first edge 436 contacts an end of a connecting edge 418 herein referred to as a first interior connecting edge 418, and the second trench first edge 440 contacts an opposite end of the first interior connecting edge 418. The first interior connecting edge 418 contains two inflection points, a first inflection point 439a and a second inflection point 439b.

The second trench second edge 442 contacts an end of a connecting edge 420 herein referred to as a second interior connecting edge 420, while the third trench first edge 446 contacts an opposite end of the second interior connecting edge 420. The second interior connecting edge 420 contains two inflection points, a third inflection point 439c and a fourth inflection point 439d.

The third trench second edge 448 contacts an end of a connecting edge 432 herein referred to as a third interior connecting edge 432, while the first trench second edge 438 contacts an opposite end of the third interior connecting edge 432 The third interior connecting edge 432 contains two inflection points, a fifth inflection point 439e and a sixth inflection point 439f.

A trench intersection radius 424 extends from the trench intersection center point 416 to the first interior connecting edge 418, to the second interior connecting edge 420, and to the third interior connecting edge 432, to define an intersection trench 422. As described for previous examples, the trench intersection radius 424 may be in a range from 50 percent to 100 percent of the greater of the first trench width 404, the second trench width 410, and the third trench width 444. Similar to previous examples, the intersection trench 422 may include a substrate contact 459.

The first interior connecting edge 418 has a first maximum radius of curvature 428 at a first connecting edge center point 426 of the first interior connecting edge 418. A first arc 428a is tangent to the first interior connecting edge 418 at the first connecting edge center point 426, and has a radius of curvature equal to the first maximum radius of curvature 428. The first maximum radius of curvature 428 may be greater than 70 percent of the greater of the first trench width 404 and the second trench width 410.

The second interior connecting edge 420 has a second maximum radius of curvature 430 at a second connecting edge center point 450 of the second interior connecting edge 420. A second arc 430a is tangent to the second interior connecting edge 420 at the second connecting edge center point 450, and has a radius of curvature equal to the second maximum radius of curvature 430. The second maximum radius of curvature 430 may be greater than 70 percent of the greater of the second trench width 410 and the third trench width 444.

The third interior connecting edge 432 has a third maximum radius of curvature 476 at a third connecting edge center point 474 of the third interior connecting edge 432. A third arc 476a is tangent to the third interior connecting edge 432 at the third connecting edge center point 474, and has a radius of curvature equal to the third maximum radius of curvature 476. The third maximum radius of curvature 476 may be greater than 70 percent of the greater of the third trench width 444 and the first trench width 404.

A first edge minimum space 452 is a minimum distance between the first interior connecting edge 418 and the first trench center line 406. The first edge minimum space 452 is less than half of the first trench width 404. A first trench neck width 454 is a minimum distance between the first interior connecting edge 418 and the third interior connecting edge 432. The first trench neck width 454 is less than the first trench width 404 and less than a maximum width of the intersection trench 422.

A second edge minimum space 456 is a minimum distance between the first interior connecting edge 418 and the second trench center line 412. The second edge minimum space 456 is less than half of the second trench width 410. A second trench neck width 458 is a minimum distance between the first interior connecting edge 418 and the second interior connecting edge 420. The second trench neck width 458 is less than the second trench width 410 and less than a maximum width of the intersection trench 422.

A third edge minimum space 460 is a minimum distance between the third interior connecting edge 432 and the third trench center line 434. The third edge minimum space 460 is less than half of the third trench width 444. A third trench neck width 462 is a minimum distance between the second interior connecting edge 420 and the third interior connecting edge 432. The third trench neck width 462 is less than the third trench width 444 and less than a maximum width of the intersection trench 422.

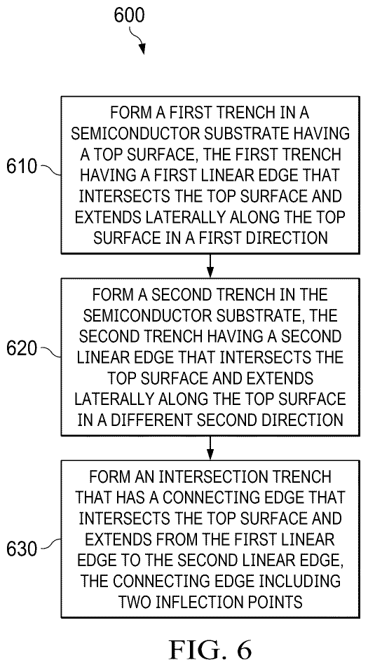

Turning now to FIG. 6, a method 600 is illustrated for manufacturing an integrated circuit according to described examples. In a step 610, a first trench is formed in a semiconductor substrate having a top surface. The first trench has a first linear edge that intersects the top surface and extends laterally along the top surface in a first direction. In a step 620, a second trench is formed in the semiconductor substrate. The second trench has a second linear edge that intersects the top surface and extends laterally along the top surface in a different second direction. In a step 630, an intersection trench is formed. The intersection trench has a connecting edge that intersects the top surface and extends from the first linear edge to the second linear edge, the connecting edge including two inflection points.

While various examples of the present disclosure have been described above, it should be understood that they have been presented by way of example and not limitation. As such, although foregoing examples are described to use various resist layers (e.g., Photoresist or photomask layers) to perform various process steps (e.g., Implant steps or etch steps), the present disclosure is not limited thereto. For example, one or more hard masks (including one or more layers) may be patterned to define various regions for subsequent process steps to be applied (e.g., Regions for receiving dopant atoms, regions to block etchants). Moreover, the resist layers may include multi-level resists instead of a single-level resist in some examples. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the following claims and their equivalents.

What is claimed is:

1. A microelectronic device, comprising:
a semiconductor substrate having a top surface;
a first trench in the semiconductor substrate having a first linear edge that intersects the top surface and extends laterally in a first direction;
a second trench in the semiconductor substrate having a second linear edge that intersects the top surface and extends laterally in a different second direction; and
a connecting edge that intersects the top surface and extends from the first linear edge to the second linear edge, the connecting edge including two inflection points.

2. The microelectronic device of claim 1, further comprising:
a third trench in the semiconductor substrate having a third linear edge that intersect the top surface and extends laterally in a third direction different than the second direction,
wherein the first trench has a fourth linear edge opposing the first linear edge, and the first linear edge and the fourth linear edges are connected by a connecting edge that includes four inflection points.

3. The microelectronic device of claim 1, further comprising:
a third trench in the semiconductor substrate having a third linear edge that intersects the top surface and extends laterally in a third direction different than the second direction,
wherein the first trench has a fourth linear edge opposing the first linear edge, and the third and fourth linear edges are connected by a linear connecting edge.

4. The microelectronic device of claim 1, wherein the first trench and the second trench are filled with a dielectric material.

5. The microelectronic device of claim 1, wherein the first trench and the second trench are filled with a polysilicon layer.

6. The microelectronic device of claim 5, further comprising a dielectric liner between the polysilicon layer and the semiconductor substrate.

7. The microelectronic device of claim 5, wherein the polysilicon layer contacts the semiconductor substrate within a intersection trench region.

8. The microelectronic device of claim 5, further comprising a metallic via within a intersection trench region that connects the polysilicon layer to an interconnect metal layer.

9. The microelectronic device of claim 1, wherein the first trench has a first width and the second trench has a second width, and further comprising an intersection trench including the connecting edge, the intersection trench having a radius less than the first and second widths.

10. The microelectronic device of claim 9, wherein the intersection trench radius is less than the first and second trench widths.

11. The microelectronic device of claim 1, wherein the first direction is normal to the second direction.

12. A method of forming an microelectronic device, comprising:
a semiconductor substrate having a top surface;
forming a first trench in a semiconductor substrate having a top surface, the first trench having a first linear edge that intersects the top surface and extends laterally along the top surface in a first direction;
forming a second trench in the semiconductor substrate, the second trench having a second linear edge that intersects the top surface and extends laterally along the top surface in a different second direction; and
forming an intersection trench that has a connecting edge that intersects the top surface and extends from the first linear edge to the second linear edge, the connecting edge including two inflection points.

13. The method of claim 12, further comprising:
forming a third trench in the semiconductor substrate having a third linear edge that intersects the top surface and extends laterally along the top surface in a third direction different than the second direction,
wherein the first trench has a fourth linear edge opposing the first linear edge, and the third and fourth linear edges are connected by a connecting edge that includes four inflection points.

14. The method of claim 12, further comprising:
forming a third trench in the semiconductor substrate having a third linear edge that intersects the top surface and extends laterally along the top surface in a third direction different than the second direction,
wherein the first trench has a fourth linear edge opposing the first linear edge, and the third and fourth linear edges are connected by a linear connecting edge.

15. The method of claim 12, wherein the first trench and the second trench are filled with a polysilicon layer.

16. The method of claim 12, wherein the first trench has a first width and the second trench has a second width, and the connecting edge is an edge of an intersection trench having a radius less than the first and second widths.

17. The method of claim 12, wherein the first direction is normal to the second direction.

18. A microelectronic device, comprising:
a semiconductor substrate having a top surface;
a first trench in the semiconductor substrate having a first trench width along a first minor axis and a extending laterally in a first direction along a first major axis;
a second trench in the semiconductor substrate having a second trench width along a second minor axis and a extending laterally in a second direction along a second major axis; and
an intersection trench connected to the first trench by a neck trench portion having a neck width less than the first trench width.

19. The microelectronic device of claim 18, wherein the intersection trench is connected to the second trench by a second neck trench portion having a neck width less than the second trench width.

20. The microelectronic device of claim 18, wherein the first and second trenches and the intersection trench are filled with polysilicon.
